(19) United States
(12) Patent Application Publication
(10) Pub. No.: US 2008/0222502 A1
(43) Pub. Date: Sep. 11, 2008

(54) ERROR DETERMINING APPARATUS AND METHOD

(75) Inventor: Tae-woo KIM, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/835,751

(22) Filed: Aug. 8, 2007

(30) Foreign Application Priority Data
Mar. 8, 2007 (KR) 2007-23194

(51) Int. Cl. H03M 13/03

(52) U.S. Cl. 714/819; 714/E11.03; 714/E11.062

(57) ABSTRACT

An error determining apparatus includes an Error Detection Code (EDC) error detector to detect an EDC error of data read from an optical disk, a continuity error detector to detect a continuity error of a currently decoded address by comparing the currently decoded address and a previously decoded address, and an error determiner to receive information on the previously determined error state and to determine a final error state of the currently decoded address of the optical disk based on the EDC error detected by the EDC error detector, the continuity error detected by the continuity error detector, and the previously determined error state.

### CROSS-REFERENCE TO RELATED APPLICATION

This application claims the benefit of Korean Application No. 2007-23194, filed Mar. 8, 2007 in the Korean Intellectual Property Office, the disclosure of which is incorporated herein by reference.

### BACKGROUND OF THE INVENTION

1. Field of the Invention

Aspects of the present invention relate to an error determining apparatus and method, and more particularly to an error determining apparatus and method to determine address validity of an optical disk

2. Description of the Related Art

Optical disks are used to record and/or reproduce data, such as digital video data and digital audio data, and are manufactured in various types. Examples include Digital Versatile Disks (DVDs) and Compact Disks (CDs). Optical disks are widely used, and various types of optical disk recording and/or reproducing apparatuses (such as DVD players and CD players) have been developed to record and/or reproduce data to and/or from an optical disk.

Physical address information is recorded on a recording surface of an optical disk. The recording address is used to randomly access data or to access a data recording location. Desired data is reproduced by discriminating between errors of the recorded address information and determining the validity of the errors.

When an optical disk is purchased for the first time, since the surface on which predetermined data is to be recorded is clean, errors hardly ever occur when an optical disk reproducing apparatus reproduces the data. However, if the optical disk is left outside of a case, such as a jewelbox, for an extended period of time, foreign matter, such as dust, adheres to the data recording surface. Also, users may damage the data recording surface due to carelessness.

When foreign matter, such as dust, adheres to the data recording surface of an optical disk, or when the data recording surface of an optical disk is otherwise damaged, a reproduction error may occur when data is reproduced from the optical disk. One way in which this error may occur is that address information may be incorrectly detected, thereby obstructing a search for a correct data reproducing location.

FIG. 1 is a block diagram of a conventional error determining apparatus 100. If information on an optical disk (not shown) loaded in an optical disk reproducing apparatus (not shown) is input to a Phase Locked Loop (PLL) 110 via a pickup unit (not shown) and an analog circuit (not shown), the PLL 110 generates a clock synchronized with a channel and detects the sync based on the clock. Data is accurately detected based on the sync and input to an Error Detection Code (EDC) decoder 120 and a continuity error detector 140.

The EDC decoder 120 performs EDC decoding suitable for a specification of the optical disk and transmits an EDC decoding result to an EDC error detector 130 to detect an EDC error. The EDC error detector 130 detects an EDC error using a codeword and parity data added to the data. The continuity error detector 140 determines whether continuity is maintained by comparing a current address and a previous address, and detects a continuity error based on a result of the continuity determination.

A final error is determined by selectively combining the EDC error detected by the EDC error detector 130 and the continuity error detected by the continuity error detector 140. The combination of the EDC error and the continuity error differs according to set values. The final error can be determined using only one of the EDC error and the continuity error or using both of the EDC error and the continuity error. For example, if both the EDC error and the continuity error are used, a valid address can be determined if both the EDC error and the continuity error do not occur. Furthermore, if only one of the EDC error or the continuity error is used, a valid address can be determined if only one of the EDC error or the continuity error does not occur.

When address validity is determined by using only the EDC error, the probability of incorrectly detecting an error is generally low. However, when a channel state is unstable, inaccurate detections of errors occur frequently. Thus, when a channel state is unstable, even if an error exists in an address, it may be incorrectly determined that no error exists in the address.

When address validity is determined using only the continuity error, the determination of a valid address may not be reliable since the existence of an error is determined based on continuity of whether an error exists in one address among a plurality of addresses, but the error may exist throughout the plurality of addresses. In addition, if abnormal patterns (i.e. errors) are continuous in a deteriorated channel state, a valid address may be incorrectly determined. If the continuity error detector 140 compares a large number of previous addresses to a current address in order to prevent an incorrect error determination, a valid address may be incorrectly detected as an invalid address. Also, since a plurality of addresses must be decoded in order to obtain one result, a response time for the continuity error detector 140 to obtain a correct determination is slow.

If both the EDC error and the continuity error are used, when an invalid address is determined by determining a final state as an error state based on determining whether at least one of the EDC error or the continuity error occurs, an error state is detected more accurately than in the above two cases. However, when a determination reference level is inaccurate, even an available and somewhat valid address may be determined as an invalid address. Furthermore, if both the EDC error and the continuity error are used, when an invalid address is determined only if both the EDC error and the continuity error occur, an incorrect detection of the EDC error prevents the accurate detection of address validity, and a valid address may be determined as invalid.

### SUMMARY OF THE INVENTION

Aspects of the present invention provide an error determining method and apparatus to prevent an incorrect detection of an error and to increase a determination reliability of an available address.

Additional aspects and/or advantages of the invention will be set forth in part in the description which follows and, in part, will be obvious from the description, or may be learned by practice of the invention.

According to an aspect of the present invention, an error determining apparatus to determine address validity of an optical disk includes an Error Detection Code (EDC) error detector to detect an EDC error of data read from the optical disk, a continuity error detector to detect a continuity error of a currently decoded address by comparing the currently decoded address and a previously decoded address; and an error determiner to receive information on a previously determined error state determined using the previously decoded address and to determine a final error state of the currently decoded address of the optical disk based on the EDC error detected by the EDC error detector, the continuity error detected by the continuity error detector.

According to an aspect of the present invention, if the previously determined error state is an “error” state, the error determiner outputs a “no error” state as the final error state when neither the EDC error nor the continuity error are detected, and if the previously determined error state is the “no error” state, the error determiner outputs the ‘error’ state as the final error state when at least the continuity error is detected.

According to an aspect of the present invention, if the previously determined error state is an “error” state, the error determiner outputs a “no error” state as the final error state when neither the EDC error nor the continuity error are detected, and outputs the “error” state as the final error state when at least one of the EDC error and the continuity error is detected, and if the previously determined error state is the “no error” state, the error determiner outputs the “error” state as the final error state when at least the continuity error is detected, and outputs the ‘no error’ state when at least the continuity error is not detected.

According to an aspect of the present invention, the continuity error detector compares the currently decoded address and the previously decoded address and detects the continuity error when a number of error bits determined by the comparison is greater than a reference level.

According to an aspect of the present invention, the continuity error detector receives the information on the previously determined error state, sets the reference level of the number of error bits according to the previously determined error state, compares the currently decoded address and the previously decoded address, and detects the continuity error if the number of error bits determined by the comparison is greater than the reference level.

According to an aspect of the present invention, the continuity error detector sets a plurality of reference levels and selectively uses one of the plurality of reference levels according to the previously determined error state.

According to an aspect of the present invention, the continuity error detector compares the currently decoded address and the previously decoded address on a bit by bit basis and detects the continuity error if the number of error bits determined by the comparison is greater than the reference level.

According to an aspect of the present invention, the continuity error detector receives the information on a previously determined error state, sets the reference level in regard to the number of error bits according to the previously determined error state, compares the currently decoded address and the previously decoded address on a bit by bit basis, and detects the continuity error if the number of error bits determined by the comparison is greater than the reference.

According to another aspect of the present invention, an error determining method of determining address validity of an optical disk includes detecting an Error Detection Code (EDC) error of data read from the optical disk, detecting a continuity error of a currently decoded address by comparing the currently decoded address and a previously decoded address, receiving information on a previously determined error state determined using the previously decoded address and determining a final error state of the currently decoded address of the optical disk based on the detected EDC error, the detected continuity error, and the previously determined error state.

According to another aspect of the present invention, if the previously determined error state is an “error” state, the determining of the final error state includes outputting a “no error” state as the final error state when neither the EDC error nor the continuity error are detected, and if the previously determined error state is the “no error” state, the determining of the final error state includes outputting the “error” state as the final error state when the continuity error is detected.

According to another aspect of the present invention, if a previously determined error state is an “error” state, the determining of the final error state includes outputting a “no error” state as the final error state when neither the EDC error nor the continuity error are detected, and outputting the “error” state as the final error state when at least one of the EDC error and the continuity error is detected, and if the previously determined error state is the “no error” state, the determining of the final error state includes outputting the “error” state as the final error state when at least the continuity error is detected, and outputting the “no error” state when at least the continuity error is not detected.

According to another aspect of the present invention, the detecting of the continuity error includes comparing the currently decoded address and the previously decoded address and detecting the continuity error when a number of error bits determined by the comparing is greater than a predetermined level.

According to another aspect of the present invention, the detecting of the continuity error includes receiving the information on the previously determined error state, setting the reference level of the number of error bits according to the previously determined error state, comparing the currently decoded address and the previously decoded address, and detecting the continuity error if the number of error bits determined by the comparing is greater than the reference level.

According to another aspect of the present invention, the setting of the reference level of the number of error bits includes setting a plurality of reference levels, and the detecting of the continuity error includes selectively using one of the plurality of reference levels according to the previously determined error state.

According to another aspect of the present invention, the detecting of the continuity error includes comparing the currently decoded address and the previously decoded address on a bit by bit basis and detecting the continuity error when the number of error bits determined by the comparing is greater than the reference level.

According to another aspect of the present invention, the detecting of the continuity error further includes receiving the information on the previously determined error state and setting the reference level in regard to the number of error bits according to the previously determined error state,; comparing the currently decoded address and the previously decoded address on a bit by bit basis, and detecting the continuity error if the number of error bits is greater than the reference level.

According to another aspect of the present invention, a computer readable recording medium encoded with a computer readable program with processing instructions for executing an error determining method of determining address validity of an optical disk includes detecting an Error Detection Code (EDC) error of data read from the optical disk, detecting a continuity error of a currently decoded address by comparing the currently decoded address and a previously decoded address, receiving information on a previously determined error state determined using the previously decoded address and determining a final error state of the currently decoded address of the optical disk based on the detected EDC error, the detected continuity error, and the previously determined error state.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a block diagram of a conventional error determining apparatus;

FIG. 2 is a block diagram of an error determining apparatus according to an embodiment of the present invention;

FIG. 3 is a block diagram of a continuity error detector according to an embodiment of the present invention;

FIG. 4 is a diagram illustrating a process of detecting a continuity error in a continuity error detector according to an embodiment of the present invention;

FIG. 5 is a state diagram illustrating a final error state in an error determiner according to an embodiment of the present invention; and

FIG. 6 is a flowchart of an error determining method according to an embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

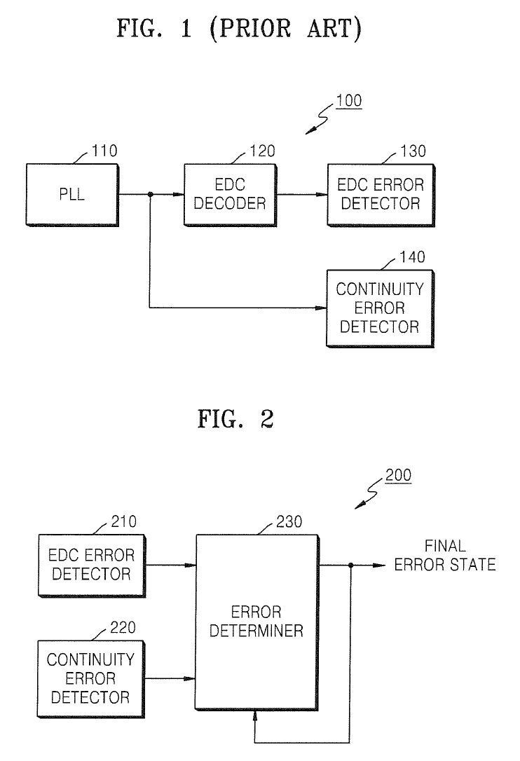

FIG. 2 is a block diagram of an error determining apparatus 200 according to an embodiment of the present invention. Referring to FIG. 2, the error determining apparatus 200 includes an Error Detection Code (EDC) error detector 210, a continuity error detector 220, and an error determiner 230. It is understood that other components may also be used with the error determining apparatus 200. A phase-locked loop (PLL) circuit and an EDC decoder, such as those shown in FIG. 1, can be similarly used in the apparatus 200. While not required, the error determining apparatus 200 can be used in a recording and/or reproducing apparatus having an optical pickup to read and/or write data to and/or from an optical disk, and which records and/or reproduces the data.

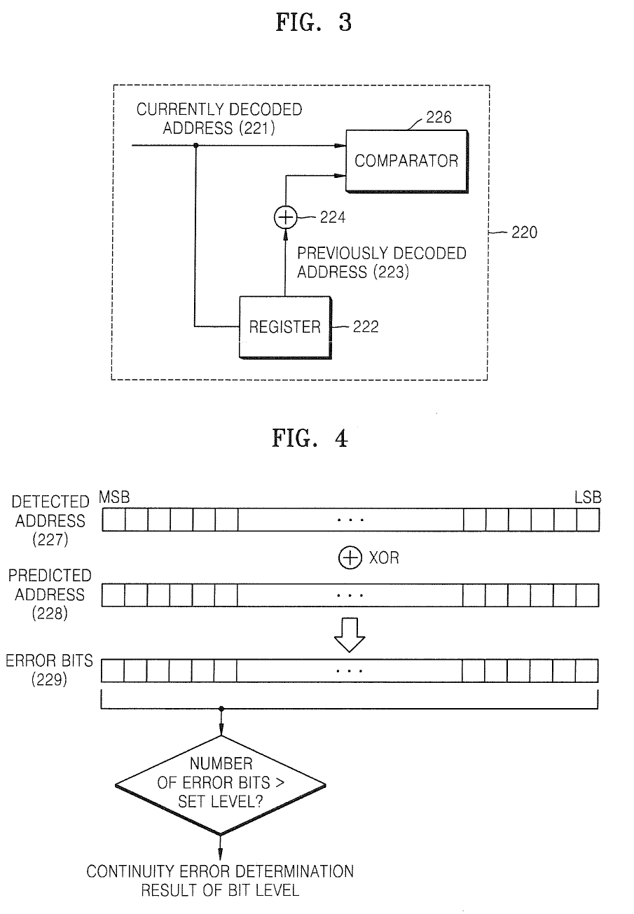

An EDC is a code used to detect whether an error has occurred. The EDC error detector 210 detects an EDC error through a decoding process which involves using a codeword and added parity data. Although not limited thereto, aspects of the present invention may employ one or a combination of Hamming Code or Reed-Solomon code as the EDC. The continuity error detector 220 detects a continuity error by comparing a currently decoded address 221 (FIG. 3) and a previously decoded address 223 (FIG. 3) and determining whether the currently decoded address 221 and the previously decoded address 223 are continuous.

The continuity error detector 220 increases the capability of determining a channel state by comparing the continuity, for example, on a bit by bit basis. Furthermore, the continuity error detector 220 compares the addresses on a bit by bit basis and detects a continuity error if even one bit is not continuous, or sets a reference level, which is a reference number of error bits, and detects the continuity error if the number of detected error bits is greater than the reference level.

Alternatively, the continuity error detector 220 may set a plurality of reference levels, in which case the continuity error detector 220 may select and apply one of the plurality of reference levels according to a previously determined error state or other conditions. It is understood that the continuity error detector 220 may set a reference level or a plurality of reference levels according to a wide variety of conditions, including conditions determined by a user or determined by other factors, such as a type of optical disk, etc.

The error determiner 230 receives information on a previously determined error state and determines a final error state based on the EDC error detected by the EDC error detector 210 and the continuity error detected by the continuity error detector 220. By using a previously determined error state in order to determine an address error state, the error determiner 230 increases the flexibility and reliability of error detection according to a channel state. Here, the term “previously determined error state” may refer to an error state determined in a previous state right before a state including the currently decoded address 221 or a result obtained by combining error states determined in two or more immediately previous states before the state including the currently decoded address 221.

FIG. 3 is a block diagram of the continuity error detector 220 according to an embodiment of the present invention. Referring to FIG. 3, if a currently decoded address 221 is input to the continuity error detector 220, the currently decoded address 221 is input to a comparator 226 in order to be compared to a previously decoded address 223. The currently decoded address 221 is input to a register 222 in order to be temporarily stored. Once the currently decoded address 221 is input to the register 222, the register 222 delays the currently decoded address 221 by a predetermined delay time, such as, for example, an amount of one clock pulse. At this point, the currently decoded address 221 becomes the previously decoded address 223 and is compared to a currently decoded address 221 decoded in a next state by the comparator 226. The previously decoded address 223 output from the register 222 is added to a predetermined magnitude by an adder 224 in order to make a comparison condition of the previously decoded address 223 the same as the currently decoded address 221 by adjusting the previously decoded address 223 according to a magnitude expected of the currently decoded address 221. However, the currently decoded address 221 can be otherwise stored as opposed to being stored in the register 222. It is further understood that the adder 224 can be applied to the currently decoded address 221 to adjust the currently decoded address 221 to an expected value of a previously decoded address 223.

The comparator 226 receives the currently decoded address 221 and the previously decoded address 223, and determines continuity based on the currently and previously decoded addresses 221 and 223. According to an aspect of the present invention, the comparator 226 compares the continuity on a bit by bit basis to increase the accuracy of determining a channel state. The comparator 226 compares the two addresses 221 and 223 on a bit by bit basis and detects a continuity error if even one bit is not continuous, or sets a reference level and detects the continuity error only if the number of detected error bits between the currently decoded address and the previously decoded address is greater than the reference level. It is thus understood that the comparator 226 is not required to compare the currently and previously decoded addresses 221 and 223 on a bit by bit basis, and may instead compare the addresses 221 and 223 on a larger scale, e.g., by comparing groups of bits to each other.

FIG. 4 is a diagram illustrating a process of detecting a continuity error using the continuity error detector 220 according to an embodiment of the present invention. Referring to FIG. 4, a detected address 227 corresponds to the currently decoded address 221, and a predicted address 228 corresponds to the address obtained by adding the predetermined value to the previously decoded address 223 output from the register 222. Each of the two addresses 227 and 228 are arranged from the most significant bit (MSB) to the least significant bit (LSB), and an Exclusive OR operation is performed on the currently decoded address 227 and the predicted address 228. Error bits 229 are detected using the Exclusive OR operation, in which the binary currently decoded address 227 and the binary predicted address 228 are compared to each other bit by bit. A binary value is obtained by outputting 0 if two compared bits are the same, or 1 if the two compared bits are different from each other. Alternatively, if two compared bits are the same a 1 can be output, and if two compared bits are different from each other, a 0 can be output.

If the number of error bits 229 (i.e. the number of bits in which the currently decoded address and the predicted address are different) is greater than a set reference level, the continuity error detector 220 determines that a continuity error has occurred. Although the continuity error detector 220 can determine that the continuity error has occurred if even one error bit exists, the flexibility of determining an available address is increased by setting a reference level and determining that the continuity error has occurred if the number of error bits is greater than the reference level.

Alternatively, the continuity error detector 220 can set a plurality of reference levels, and select and apply one of the plurality of reference levels according to a previously determined error state output from the error determiner 230 as a prior final error state. For example, the continuity error detector 220 can perform the continuity determination by selecting a lower reference level with fewer error bits from among the plurality of levels for a strict determination if the previously determined error state is an “error” state or selecting a higher reference level with more error bits if the previously determined error state is a “no error” state. The continuity error detector 220 can use the plurality of reference levels in various ways to adjust the strictness of the error determination operation. Further, the reference levels can be set by a user of the apparatus 200, can be predetermined by the manufacturer, and/or can be developed/learned by the apparatus 200 during operation.

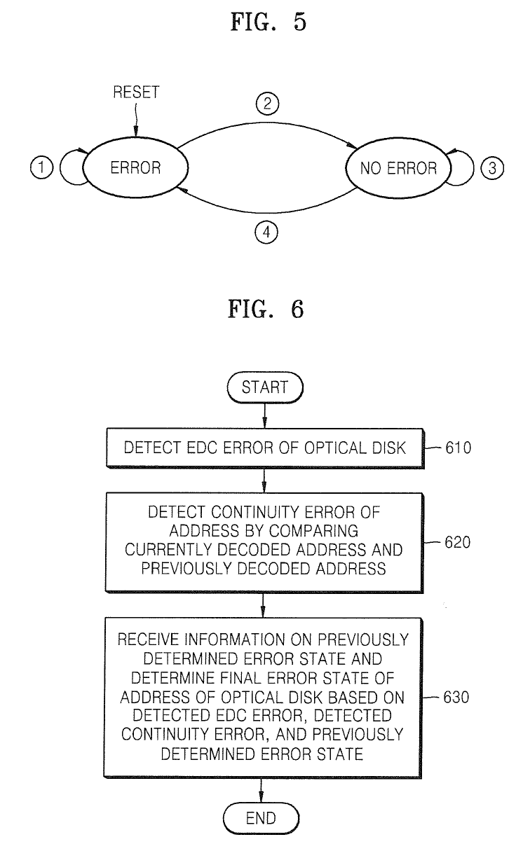

FIG. 5 is a state diagram illustrating a final error state in the error determiner 230 according to an embodiment of the present invention. The error determiner 230 determines a final error state of a currently decoded address 221 by receiving both the currently decoded address 221 and a previously decoded address 223. Accordingly, the error determiner 230 can accurately determine an error if a channel state is unstable by detecting when a previously determined error state is an “error” state. For example, if the previously determined error state is the “error” state, the final error state is changed to a “no error” state (\textcircled{2} of FIG. 5) only if neither an EDC error nor a continuity error are detected. Otherwise, the final error state maintains the “error” state (\textcircled{1} of FIG. 5) even though one of the EDC error or the continuity error indicates no error.

If the previously determined error state is the “no error” state, this “no error” state indicates that a previous address is stable, and the final error state can be determined more easily. For example, the final error state is changed to the “error” state (\textcircled{4} of FIG. 5) only if a continuity error determination result is “error”. Otherwise, the final error state maintains the “no error” state (\textcircled{3} of FIG. 5). Alternatively, if the EDC error is the only error detected, the final error state can also be changed to the “error” state (\textcircled{4} of FIG. 5).

FIG. 6 is a flowchart of an error determining method according to an embodiment of the present invention. Referring to FIG. 6, an error detection code (EDC) error of an optical disk is detected at operation 610. The EDC is a code used to detect whether an error has occurred, such as by using a codeword and added parity data. The detected EDC error is used to determine whether a final error exists in an address of an optical disk.

In operation 620, a continuity error of a currently decoded address 221 is detected by comparing the currently decoded address 221 and a previously decoded address 223. According to an aspect of the present invention, the continuity is determined by comparing the currently decoded address 221 and the previously decoded address 223 on a bit by bit basis to increase the capability of determining a channel state. The addresses 221 and 223 are compared on a bit by bit basis and a continuity error is detected if even one bit is not continuous, or if the number of error bits 229 is greater than a set reference level.

In operation 630, information on a previously determined error state is received, and a final error state is determined based on the detected EDC error, the detected continuity error, and the previously determined error state. In order to increase the flexibility and reliability of error detection according to a channel state, the previously determined error state is considered even when a final error state of an address is determined.

Aspects of the present invention may be written as computer programs and may further be implemented in general-use digital computers that execute the programs using a computer readable recording medium. Examples of the computer readable recording media include magnetic storage media (e.g., ROM, floppy disks, hard disks, etc.), optical recording media (e.g., CD-ROMs, or DVDs), and storage media such as carrier waves (e.g., transmission through the Internet).

As described above, aspects of the present invention prevent incorrect error detection and increase error determination reliability by changing a determination condition according to a previously determined error state. While described in the context of error detection for optical media such as CDs and DVDs, it is understood that aspects can be applied to other optical media and/or non-optical media.

In addition, aspects of the present invention may be used to determine continuity on a bit by bit level in order to set a reference level which can be used as a parameter for system level optimization.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An error determining apparatus to determine address validity of an optical disk, the apparatus comprising:
an Error Detection Code (EDC) error detector to detect an EDC error of data read from the optical disk;
a continuity error detector to detect a continuity error of a currently decoded address by comparing the currently decoded address and a previously decoded address; and
an error determiner to receive information on a previously determined error state determined using the previously decoded address and to determine a final error state of the currently decoded address of the optical disk based on the EDC error detected by the EDC error detector, the continuity error detected by the continuity error detector, and the previously determined error state.

2. The apparatus of claim 1, wherein:
if the previously determined error state is an “error” state, the error determiner outputs a “no error” state as the final error state when neither the EDC error nor the continuity error are detected, and
if the previously determined error state is the “no error” state, the error determiner outputs the “error” state as the final error state when at least the continuity error is detected.

3. The apparatus of claim 1, wherein:
if the previously determined error state is an “error” state, the error determiner outputs a “no error” state as the final error state when neither the EDC error nor the continuity error are detected, and outputs the “error” state as the final error state when at least one of the EDC error or the continuity error is detected, and
if the previously determined error state is the “no error” state, the error determiner outputs the “error” state as the final error state when at least the continuity error is detected, and outputs the “no error” state when at least the continuity error is not detected.

4. The apparatus of claim 1, wherein the continuity error detector compares the currently decoded address and the previously decoded address and detects the continuity error when a number of error bits determined by the comparison is greater than a reference level.

5. The apparatus of claim 4, wherein the continuity error detector receives the information on the previously determined error state, sets the reference level of the number of error bits according to the previously determined error state, compares the currently decoded address and the previously decoded address, and detects the continuity error if the number of error bits determined by the comparison is greater than the reference level.

6. The apparatus of claim 5, wherein the continuity error detector sets a plurality of reference levels and selectively uses one of the plurality of reference levels according to the previously determined error state.

7. The apparatus of claim 4, wherein the continuity error detector compares the currently decoded address and the previously decoded address on a bit by bit basis, and detects the continuity error if the number of error bits determined by the comparison is greater than the reference level.

8. The apparatus of claim 7, wherein the continuity error detector receives the information on a previously determined error state, sets the reference level in regard to the number of error bits according to the previously determined error state, compares the currently decoded address and the previously decoded address on a bit by bit basis, and detects the continuity error if the number of error bits determined by the comparison is greater than the reference level.

9. The apparatus of claim 1, wherein the continuity error detector comprises:
an adder to add a predetermined magnitude to the previously decoded address, the predetermined magnitude being sufficient to compare the previously decoded address to the currently decoded address;
a comparator to compare the currently decoded address with the previously decoded address received from the adder; and
a register to temporarily store the currently decoded address for a predetermined delay time to obtain another previously decoded address for a next comparison and which stores the previously decoded address used by the adder.

10. The apparatus of claim 1, wherein the previously determined error state comprises one of an error state determined in a previous state right before a state including the currently decoded address or a result obtained by combining error states determined in two or more previous states before the state including the currently decoded address.

11. An error determining method of determining address validity of an optical disk, the method comprising:
detecting an Error Detection Code (EDC) error of data read from the optical disk;
detecting a continuity error of a currently decoded address by comparing the currently decoded address and a previously decoded address;
receiving information on a previously determined error state determined using the previously decoded address; and
determining a final error state of the currently decoded address of the optical disk based on the detected EDC error, the detected continuity error, and the previously determined error state.

12. The method of claim 11, wherein:
if the previously determined error state is an “error” state, the determining of the final error state comprises outputting a “no error” state as the final error state when neither the EDC error nor the continuity error are detected, and
if the previously determined error state is the “no error” state, the determining of the final error state comprises outputting the ‘error’ state as the final error state when at least the continuity error is detected.

13. The method of claim 11, wherein:
if the previously determined error state is an “error” state, the determining of the final error state comprises outputting a “no error” state as the final error state when neither the EDC error nor the continuity error are detected, and outputting the “error” state as the final error state when at least one of the EDC error and the continuity error is detected, and
if the previously determined error state is the “no error” state, the determining of the final error state comprises outputting the “error” state as the final error state when at least the continuity error is detected, and outputting the “no error” state when at least the continuity error is not detected.

14. The method of claim 11, wherein the detecting of the continuity error comprises comparing the currently decoded address and the previously decoded address and detecting the continuity error when a number of error bits determined by the comparing is greater than a reference level.

15. The method of claim 14, wherein the detecting of the continuity error further comprises:
receiving the information on the previously determined error state;
setting the reference level of the number of error bits according to the previously determined error state; and
comparing the currently decoded address and the previously decoded address; and
detecting the continuity error if the number of error bits determined by the comparing is greater than the reference level.

16. The method of claim 15, wherein the setting of the reference level of the number of error bits comprises setting a plurality of reference levels, and
the detecting of the continuity error comprises selectively using one of the plurality of reference levels according to the previously determined error state.

17. The method of claim 14, wherein the detecting of the continuity error comprises:
comparing the currently decoded address and the previously decoded address on a bit by bit basis, and
detecting the continuity error when the number of error bits determined by the comparing is greater than the reference level.

18. The method of claim 17, wherein the detecting of the continuity error further comprises:
receiving the information on the previously determined error state and setting the reference level in regard to the number of error bits according to the previously determined error state;
comparing the currently decoded address and the previously decoded address on a bit by bit basis; and
detecting the continuity error if the number of error bits is determined by the comparing is greater than the reference level.

19. The method of claim 11, wherein the detecting of the continuity error comprises:
adding a predetermined magnitude to the previously decoded address, the predetermined magnitude being sufficient to compare the previously decoded address to the currently decoded address;
comparing the currently decoded address with the previously decoded address; and
storing the currently decoded address for a predetermined delay time to obtain another previously decoded address for a next comparison, and storing the previously decoded address used in the adding.

20. The method of claim 11, wherein the determining of the final error state comprises using the previously determined error state which is one of an error state determined in a previous state right before a state including the currently decoded address or a result obtained by combining error states determined in two or more previous states before the state including the currently decoded address.

21. An error determining apparatus to determine address validity of an optical disk, the apparatus comprising:
a continuity error detector to detect a continuity error of a currently decoded address determined by comparing the currently decoded address, a previously decoded address, and a previously determined error state determined using the previously decoded address; and
an error determiner to determine whether the currently decoded address is valid using the continuity error, a received Error Detection Code (EDC) error of date read from the optical disk, and the previously determined error state previously determined by the error determiner.

22. The error determining apparatus of claim 21, wherein the continuity error detector receives information on the previously determined error state, sets a reference level of a number of error bits according to the previously determined error state, compares the currently decoded address and the previously decoded address, and detects the continuity error if the number of error bits determined by the comparison is greater than the reference level.

23. The error determining apparatus of claim 21, wherein the continuity error detector sets a plurality of reference levels and selectively uses one of the plurality of reference levels according to the previously determined error state.

24. The error determining apparatus of claim 23, wherein the continuity error detector uses a low reference level with fewer of the error bits for a strict determination when the previously determined error state is an “error” state and uses a higher reference level with more of the error bits when the previously determined error state is a “no error” state.

25. The error determining apparatus of claim 21, wherein:
if the previously determined error state is an “error” state, the error determiner outputs a “no error” state as the final error state when neither the EDC error nor the continuity error are detected and otherwise outputs the “error” state, and
if the previously determined error state is the “no error” state, the error determiner outputs the “error” state as the final error state when the continuity error is detected and otherwise outputs the “no error” state.

26. An error determining method of determining address validity of an optical disk, the method comprising:
detecting a continuity error of a currently decoded address by comparing the currently decoded address, a previously decoded address, and a previously determined error state determined using the previously decoded address; and
determining whether a currently decoded address of an optical disk is valid using the continuity error, a received Error Detection Code (EDC) error and the previously determined error state.

27. The method of claim 26, further comprising:
setting a plurality of reference levels; and
selectively using one of the plurality of reference levels according to the previously determined error state.

28. The method of claim 27, wherein the selectively using one of the plurality of reference levels comprises using a low reference level with fewer error bits for a strict determination when the previously determined error state is an “error” state, and using a higher reference level with more of the error bits when the previously determined error state is a “no error” state.

29. The method of claim 26, wherein the determining of whether the currently decoded address is valid comprises:
if the previously determined error state is an “error” state, determining that a final error state of the currently decoded address is a “no error” state when neither the EDC error nor the continuity error are detected and otherwise determining that the final error state is the “error” state, and
if the previously determined error state is the “no error” state, determining that the final error state is the “error” state when the continuity error is detected and otherwise determining that the final error state is the “no error” state.
